(19) United States
(12) Patent Application Publication
(10) Pub. No.: US 2009/0323758 A1
(43) Pub. Date: Dec. 31, 2009

(54) ANALOG-DIGITAL CONVERTER AND TEMPERATURE INFORMATION OUTPUT DEVICE HAVING THE SAME

(75) Inventor: Jong-Man Im, Gyeonggi-do (KR)

Correspondence Address: IP & T Law Firm PLC, 7700 Little River Turnpike, Suite 207, Fairfax, VA, 22003, US

(73) Assignee: HYNIX SEMICONDUCTOR, INC., Gyeonggi-do (KR)

(21) Appl. No.: 12/327,450

(22) Filed: Dec. 3, 2008

(30) Foreign Application Priority Data
Jun. 30, 2008 (KR) 10-2008-0063165

(51) Int. Cl. G01K 1/00; H03M 1/12

(52) U.S. Cl. 374/100; 341/155; 374/E03.001

(57) ABSTRACT

There is provided an analog-digital converter, including: a counting control unit configured to output a counting control signal which is activated while an input voltage is discharged to a predetermined voltage; and a counting unit configured to count an input clock during an activated section of the counting control signal, and output a digital code.

### CROSS-REFERENCE TO RELATED APPLICATION

The present invention claims priority of Korean patent application number 10-2008-0063165, filed on Jun. 30, 2008, which is incorporated by reference in its entirety.

### BACKGROUND OF THE INVENTION

The present invention relates to an analog digital converter and a temperature information output device having the same, and more particularly, to an analog digital converter and a temperature information output device having the same for reducing an area and improving high accuracy.

An analog-digital converter is a device for converting an analog signal into a digital signal. For example, the analog-digital converter converts an analog voltage into a digital code corresponding to the analog voltage.

Hereinafter, a temperature information output device having the analog-digital converter will be described.

The temperature information output apparatus adjusts a refresh period based on a temperature in a semiconductor memory device.

FIG. 1 is a block diagram illustrating a conventional temperature information output device having an analog-digital converter.

As shown in FIG. 1, the conventional temperature information output device having the analog-digital converter includes a temperature detection unit 100 and an analog-digital converter 110.

In details, the temperature detection unit 100 detects a temperature by using a bipolar junction transistor having a base-emitter voltage variation of about −1.8 mV/° C. in a band-gap circuit which is independent on a temperature or a power voltage variation of an element.

The temperature detection unit 100 outputs a first voltage VTEMP corresponding to a temperature one to one by amplifying a base-emitter voltage of the bipolar junction transistor. That is, as the temperature is high, the temperature detection unit 100 outputs a low base-emitter voltage of the bipolar junction transistor.

The analog-digital converter 110 includes a voltage comparison unit 120, a counting unit 130 and a converting unit 140. The analog-digital converter 110 converts and outputs the first voltage outputted from the temperature detection unit into a temperature information code as a digital code.

The voltage comparison unit 120 compares the first voltage VTEMP with a second voltage DACOUT. If a voltage level of the first voltage VTEMP is lower than a voltage level of the second voltage, the voltage comparison unit outputs a decrease signal DEC for decreasing a temperature information code THERMAL CODE which is previously set by the counting unit 130

If the voltage level of the first voltage VTEMP is higher than the voltage level of the second voltage DACOUT, the voltage comparison unit outputs an increase signal INC for increasing the temperature information code THERMAL CODE which is previously set by the counting unit 130

The counting unit 130 receives the increase signal INC or the decrease signal DEC as a control signal from the voltage comparison unit, and outputs the temperature information code THERMAL CODE having temperature information by increasing or decreasing a predetermined digital code.

The converting unit 140 as a digital-analog converter outputs an analog voltage value in response to the temperature information code THERMAL CODE as a digital value outputted from the counting unit. The converting unit 140 receives predetermined voltages VULIMIT and VLLIMIT for setting a maximum value and a minimum value of the variation of the second voltage DACOUT.

That is, the analog-digital converter 110 compares the first voltage VTEMP with the second voltage DACOUT, and increases or decreases the temperature information code THERMAL CODE.

The first voltage VTEMP is tracked using the second voltage DACOUT. When the tracking is completed, the temperature information code THERMAL CODE is a digital-converted value of the first voltage.

As described above, the analog-digital converter 110 uses a tracking method for tracking the first voltage VTEMP with the second voltage DACOUT. Accordingly, this analog-digital converter is called as a tracking type analog-digital converter.

However, the tracking type analog-digital converter has problems that an additional installation of a digital-analog converter occupies a large area, and needs a larger area to increase accuracy of the analog-digital converter.

Moreover, the tracking method has demerits that because the first voltage VTEM is tracked using the second voltage DACOUT which is digitally varied, the accuracy of the analog-digital converter is limited.

### SUMMARY OF THE INVENTION

Embodiments of the present invention are directed to providing an analog digital converter and a temperature information output device having the same for reducing an area and improving the accuracy.

In accordance with an aspect of the present invention, there is provided an analog-digital converter, including: a counting control unit configured to output a counting control signal which is activated while an input voltage is discharged to a predetermined voltage; and a counting unit configured to count an input clock during an activated section of the counting control signal, and output a digital code.

In accordance with another aspect of the present invention, there is provided a temperature information output device, including: a temperature detection unit configured to detect a temperature and output a temperature voltage varied according to the detected temperature; a counting control unit configured to a counting control signal which is activated during a discharge time of the temperature voltage to a predetermined voltage level; and a counting unit configured to count a clock inputted during an activated section of the counting control signal and output a temperature information code.

### BRIEF DESCRIPTION OF THE DRAWINGS

FIG. 1 is a block diagram illustrating a conventional temperature information output device having an analog-digital converter.

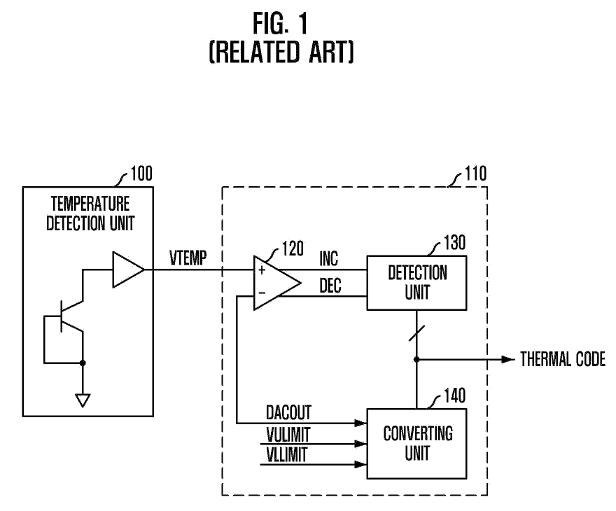

FIG. 2 is a block diagram illustrating an analog-digital converter in accordance with an embodiment of the present invention.

FIG. 3 illustrates a clock counting section of a counting unit shown in FIG. 2.

FIG. 4 is a block diagram illustrating a temperature information output device in accordance with an embodiment of the present invention.

### DESCRIPTION OF SPECIFIC EMBODIMENTS

Hereinafter, an internal generation circuit of a semiconductor memory device in accordance with the present invention will be described in detail with reference to the accompanying drawings.

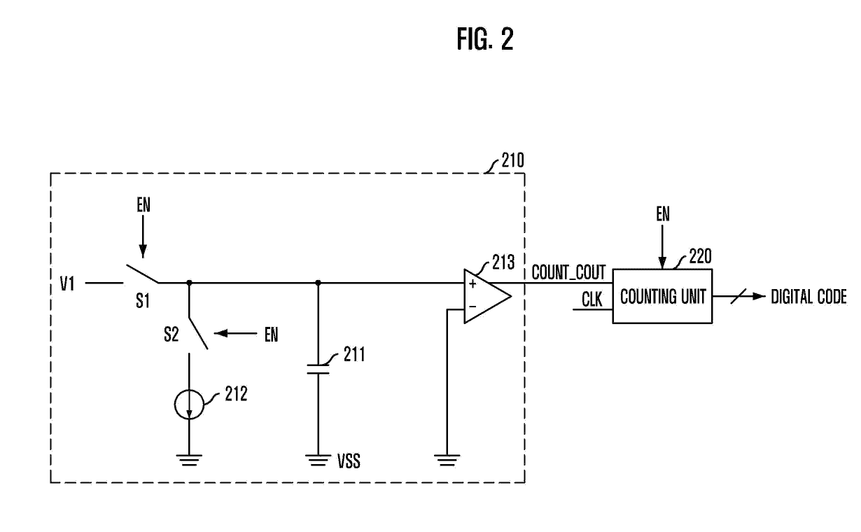

FIG. 2 is a block diagram illustrating an analog-digital converter in accordance with an embodiment of the present invention.

An analog-digital converter in accordance with an embodiment of the present invention includes a counting control unit 210, and a counting unit.

The counting control unit 210 outputs a counting control signal COUNT_CONT which is enabled during a discharge time of an input voltage V1 to a predetermined voltage level VSS. The counting control unit 210 controls the counting unit to count a digital-code DIGITAL CODE.

The counting control unit 210 includes a charging unit 211, a discharging unit 212 and a comparison unit 213. The charging unit 211 is charged as the input voltage V1, and is discharged when the enable signal EN is activated.

The charging unit 211 is configured with an element, e.g., a capacitor as shown in FIG. 2, having a charging function. If the capacitance of the capacitor increases, a discharging time of the input voltage V1 to a predetermined voltage VSS increases, but an accurate digital code DIGITAL CODE is generated.

On the contrary, if the capacitance of the capacitor decreases, the discharging time of the input voltage V1 to the predetermined voltage VSS decreases, but the accuracy of the digital code DIGITAL CODE is lowered. Accordingly, the capacitance of the capacitor is adjusted properly.

The discharging unit discharges the charge of the charging unit 211 when the enabled signal EN is activated. It is preferred that the discharging unit is configured as a current source to uniformly maintain a quantity of the discharged charge. The discharging unit may be configured with any elements for discharging a current of the charging unit 211. For example, the discharging unit may be configured with resistors.

The comparison unit 213 compares a voltage level of the charging unit 211 with the predetermined voltage VSS and outputs the counting control signal COUNT_CONT.

If the voltage level of the charging unit 211 is higher than the predetermined voltage VSS, the comparison unit 213 activates the counting control signal COUNT_CONT as “high”. If the charging unit 211 is discharged and reaches the predetermined voltage VSS, the comparison unit 213 inactivates the counting control signal COUNT_CONT as “low”.

As shown in FIG. 2, the predetermined voltage uses a ground voltage VSS, but the predetermined voltage may use a different voltage level which is lower than the input voltage V1.

If the predetermined voltage is the ground voltage VSS, when the voltage of charging unit 211 reaches the ground voltage VSS, the comparison unit 213 inactivates the counting control signal COUNT_CONT as “low” by designing to have an offset.

The counting unit 220 is enabled from an activation time of the enable signal EN, and generates the digital code DIGITAL CODE by counting an input clock CLK while the counting control signal COUNT_CONT is activated as “high”.

That is, the counting unit 220 counts the input clock if the enable signal EN and the counting control signal COUNT_CONT are activated as “high”.

The digital code DIGITAL CODE outputted from the counting unit 220 is a digitally converted value of the input voltage V1. Hereinafter, a whole operation of the analog-digital converter in accordance with an embodiment of the present invention will be described.

While the enable signal EN is inactivated, a first switch S1 maintains an on-state, and the charging unit 211 is charged as the input voltage V1. If the enable signal EN is activated, the first switch S1 is switched off, and a second switch is switched on. Accordingly, the charging unit 211 is discharged by the discharging unit 212.

When the voltage of the charging unit 211 is higher than the predetermined voltage VSS, the counting control signal COUNT_CONT is activated and outputted as “high”. Accordingly, the counting unit 220 counts the input clock CLK and generates the digital code DIGITAL CODE.

If the voltage of the charging unit 211 reaches the predetermined voltage VSS, the counting control signal COUNT_CONT is inactivated as “low”. Accordingly the counting unit 220 stops to count the input clock CLK, and the digital code DIGITAL CODE is digitally converted value of the input voltage V1.

The analog-digital converter of the present invention including the charging unit 211, the discharging unit 212, the comparison unit 213 and the counting unit 220 occupies a smaller area than a conventional analog-digital converter.

Moreover, the analog-digital converter of the present invention improves the accuracy of the digital code DIGITAL CODE conversion of the input voltage V1 by increasing a frequency of a clock CLK.

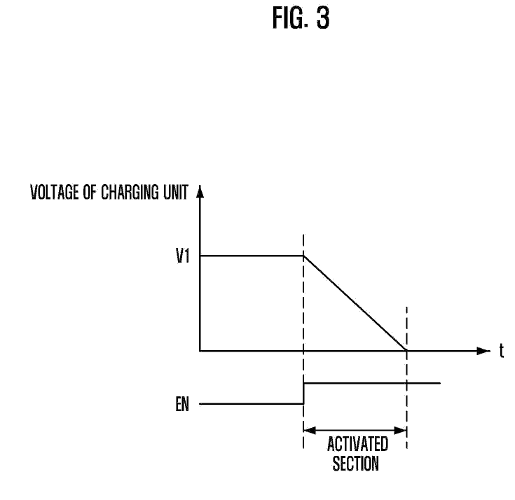

FIG. 3 illustrates a clock counting section of a counting unit and a voltage level variation of a charging unit according to a time.

As referring to FIG. 3, an operation of the analog-digital converter in accordance with an embodiment of the present invention is clearly shown.

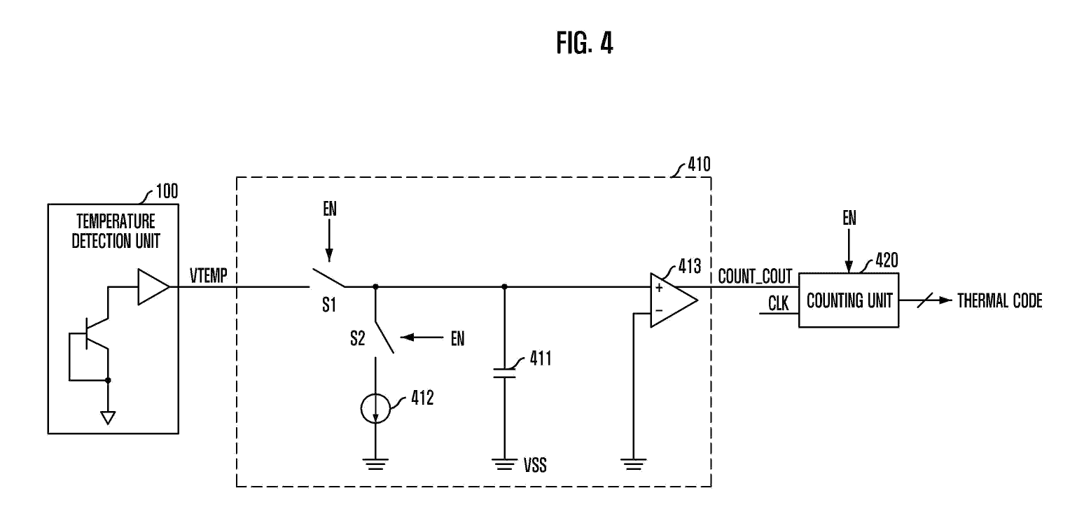

FIG. 4 is a block diagram illustrating a temperature information output device in accordance with an embodiment of the present invention.

The temperature information output device includes detection unit 430, a counting control unit 410, and a counting unit 420.

The temperature detection unit 430 detects a temperature and outputs a temperature voltage VTEMP which is varied by the detected temperature.

The counting control unit 410 outputs a counting control signal COUNT_CONT which is activated while the temperature voltage VTEMP is discharged to a level of a predetermined voltage VSS. The counting unit 420 counts a clock CLK inputted when the counting control signal COUNT_CONT is activated, and outputs a temperature information code THERMAL CODE.

Because the temperature detection unit 430 is described in a background of the present invention, and those skilled in the art may design the temperature detection unit easily, the detailed description of the temperature detection unit 430 is omitted.

Furthermore, because the counting control unit 410 and the counting unit 420 are same with the counting control unit 210 and the counting unit 220 shown in FIG. 2 except the temperature voltage which is used instead of the input voltage V1 shown in FIG. 2, the detailed descriptions of the counting control unit 410 and the counting unit 420 are omitted.

While the present invention has been described with respect to the specific embodiments, it will be apparent to those skilled in the art that various changes and modifications may be made without departing from the spirit and scope of the invention as defined in following claims.

What is claimed is:

1. An analog-digital converter, comprising:
a counting control unit configured to output a counting control signal which is activated while an input voltage is discharged to a predetermined voltage; and
a counting unit configured to count an input clock during an activated section of the counting control signal, and output a digital code.

2. An analog-digital converter, comprising:
a charging unit configured to be discharged when an enable signal is activated;
a discharging unit configured to allow the charging unit to be discharged when the enable signal is activated;
a comparison unit configured to compare a voltage level of the charging unit with a predetermined voltage level and output a counting control signal; and
a counting unit configured to count a clock and output a digital code in response to the counting control signal and the enable signal.

3. The analog-digital converter as recited in claim 2, wherein the charging unit includes a capacitor.

4. The analog-digital converter as recited in claim 2, wherein the discharging unit includes a current source for uniformly maintaining a quantity of the discharged charge.

5. A temperature information output device, comprising:
a temperature detection unit configured to detect a temperature and output a temperature voltage varied according to the detected temperature;
a counting control unit configured to a counting control signal which is activated during a discharge time of the temperature voltage to a predetermined voltage level; and
a counting unit configured to count a clock inputted during an activated section of the counting control signal and output a temperature information code.

6. The temperature information output device as recited in claim 5, wherein the counting control unit includes:
a charging unit configured to be discharged when an enable signal is activated;
a discharging unit configured to allow the charging unit to be discharged when the enable signal is activated; and
a comparison unit configured to compare a voltage level of the charging unit with a predetermined voltage level and output a counting control signal.

7. The temperature information output device as recited in claim 6, wherein the charging unit includes a capacitor.

8. The temperature information output device as recited in claim 6, wherein the discharging unit includes a current source for uniformly maintaining a quantity of the discharged charge.
